(19) United States
(12) Patent Application Publication
(10) Pub. No.: US 2016/0111375 A1
(43) Pub. Date: Apr. 21, 2016

(54) TEMPORARY BONDING OF PACKAGES TO CARRIER FOR DEPOSITING METAL LAYER FOR SHIELDING

(71) Applicant: Tango Systems, Inc., San Jose, CA (US)

(72) Inventor: Wilfried Bair, Sunnyvale, CA (US)

(21) Appl. No.: 14/517,515

(22) Filed: Oct. 17, 2014

(51) Int. Cl. H01L 23/552; H01L 21/683; H01L 21/285; H01L 21/3205

(52) U.S. Cl. CPC H01L 23/552; H01L 21/32051; H01L 21/6835; H01L 21/2855; H01L 2221/68381

(57) ABSTRACT

Techniques for batch processing LGA and BGA packages for forming a very thin conformal metal film over the packages are described. An array of the packages is mounted on a carrier wafer coated with an adhesive layer. For BGA packages, there is a significant space between the bottom of the package body and the bottom of the balls, and this space must be blocked during the PVD process for forming the metal film. The techniques include ways to accommodate the thickness of the BGA while forming a seal around the perimeter of the package body during the metal deposition process. After the carrier wafer is removed from the PVD chamber, a pick and place vacuum nozzle pulls up on each package vertically. The force tears the thin metal film around the bottom edges of the package, resulting in a shielded package.

### FIELD OF THE INVENTION

This invention relates to metal shielding of integrated circuit packages and, in particular, to techniques for supporting the packages while depositing a metal film over the packages.

### BACKGROUND

Certain types of packaged circuitry, such as a packaged integrated circuit, may create electromagnetic interference (EMI) or are susceptible to EMI. For example, RF-generating circuits or switching regulators may generate EMI. It is known to cover a package with a conductive shielding material to block such radiation. Such processes add significant time and cost to the fabrication process.

Packages which include terminals that extend from the package body are particular difficult to shield since, if the metal shield layer is sprayed on or sputtered on the package, the terminals must somehow be protected from the conductive shielding material. One such package is a ball grid array (BGA) package, where solder balls are located in an array on the bottom of the package. The solder balls may have diameters up to 400 microns.

What is needed is an efficient process for fabricating shielded packages, especially BGA packages.

### SUMMARY

In one embodiment, a rigid, reusable carrier wafer is provided. The carrier wafer is preferably a standard size for a sputtering chamber or other type of physical vapor deposition (PVD) chamber. The carrier wafer material may be silicon, glass, ceramic, metal, etc.

A tacky, but weak, adhesive layer is deposited over the surface of the carrier wafer, such as by spraying, spinning, or laminating. The adhesive layer will have some resiliency.

An array of packages is then affixed to the adhesive so that the bottom surface of the packages contact the adhesive and are weakly secured in place. The packages may then be processed as a batch in the PVD chamber for depositing a thin, conformal metal film over the tops and sides of the packages. In the PVD chamber, freed metal atoms (e.g., sputtered or evaporated) are inherently directed toward the packages at a variety of angles. Care must be taken that the metal does not short any package terminals on the bottom of the package.

For land grid array (LGA) packages, the terminals are on the bottom of the package and are flat. The package material generally forms a solder mask around each of the lands in the LGA, so the metal lands do not extend below the package body. Even if the package body does not form a solder mask around the lands, the metal lands are very thin and are spaced from the edges of the package. Accordingly, for such LGA packages, the bottom of the packages can be affixed to the adhesive without concern that metal deposited in the PVD chamber will extend under the package body and short the lands.

For BGA packages, however, there is a significant space between the bottom of the package body and the bottom of the balls, where the bottom of the balls makes contact with the adhesive layer. Therefore, various designs of the carrier wafer, or the adhesive layer, or a spacer layer (referred to as a stencil) are provided to cause the perimeter of the bottom surface of the package body to form a seal around the BGA so that the balls are protected from the deposited metal. Some designs include: forming recesses in the carrier wafer for accommodating the thickness of the BGA layer; forming the adhesive layer with openings for the BGA; forming a relatively thick and resilient adhesive layer where the BGA is pushed into the adhesive layer; and providing a mask (i.e., a stencil) over the adhesive layer with openings for the BGA where the BGA contacts the adhesive layer and the mask forms a seal around the perimeter of the bottom surface of the package body.

The carrier wafers supporting the arrays of packages are then placed in a PVD chamber, and a very thin metal film is deposited over the exposed surfaces of the packages and carrier wafer.

After the carrier wafer is removed from the PVD chamber, a vacuum nozzle of an automatic pick and place tool then attaches to the top surface of each package and pulls up on each package. The force tears the thin metal film along the bottom edges of the package, resulting in a shielded package.

In embodiments where the BGA is embedded in a soft adhesive layer having a porous structure, the heating and vacuum environment during the PVD process causes the adhesive layer to be more dense. This effectively locks the BGA in the adhesive layer. To release the packages from the adhesive layer, a solvent vapor is introduced into the PVD chamber or into a vacuum chamber other than the PVD chamber, which is absorbed by the adhesive to soften it. The packages are then easily lifted away from the carrier wafer.

After all the packages have been removed, the carrier wafer is then cleaned and reused.

In another embodiment, a stretchable tacky tape is used to support the packages during the metal deposition process. To prevent metal being deposited between the bottom of the package body and the tape, a mask (a stencil) is provided over the tape to provide openings for the BGA and form a seal around the perimeter of the package body.

Additional embodiments are described.

### BRIEF DESCRIPTION OF DRAWINGS

FIG. 1 is a perspective view of a plastic or ceramic package housing circuitry, showing the top and side surfaces of the package.

FIG. 2A is a bottom view of a BGA package.

FIG. 2B is a side view of the BGA package.

FIG. 3A is a bottom view of an LGA package.

FIG. 3B is a side view of the LGA package.

FIG. 4 is a top down view of an array of packages mounted on a reusable circular carrier wafer.

FIG. 5 is a top down view of an array of packages mounted on a reusable square carrier wafer.

FIGS. 6A-6C illustrate a process where LGA packages supported on a carrier wafer have a metal film deposited over them, and the shielded packages are then removed from the wafer. The various cross-sectional views of the carrier wafer in the figures only show a small number of the packages undergoing a batch process.

FIGS. 7A-7C illustrate a process where the BGA portion of packages are positioned in recesses in a carrier wafer have a metal film deposited over them, and the shielded packages are then removed from the wafer.

FIGS. 8A-8C illustrate a process where the BGA portion of packages are positioned in openings in an adhesive layer on a carrier wafer have a metal film deposited over them, and the shielded packages are then removed from the wafer.

FIGS. 9A-9D illustrate a process where the BGA portion of packages is pushed through a relatively hard skin of an adhesive layer to accommodate the thickness of the BGA, where the packages then have a metal film deposited over them, and the shielded packages are then removed from the wafer.

FIGS. 10A-10D illustrate a process where the BGA portion of packages is positioned in openings in a spacer layer (a stencil) to contact an adhesive layer on a carrier wafer, where the packages then have a metal film deposited over them, and the shielded packages are then removed from the wafer.

FIGS. 11A-11E illustrate a process where the BGA portion of packages is positioned in openings in a spacer layer to contact an adhesive layer on a stretchable tacky tape, where the packages then have a metal film deposited over them, and the shielded packages are then removed from the tape.

FIG. 12 is a flowchart describing a process where the adhesive is softened by a solvent vapor after the metal deposition step to allow the packages to be easily released from the adhesive.

Elements identified with the same numbers in the various figures are the same or similar.

### DETAILED DESCRIPTION

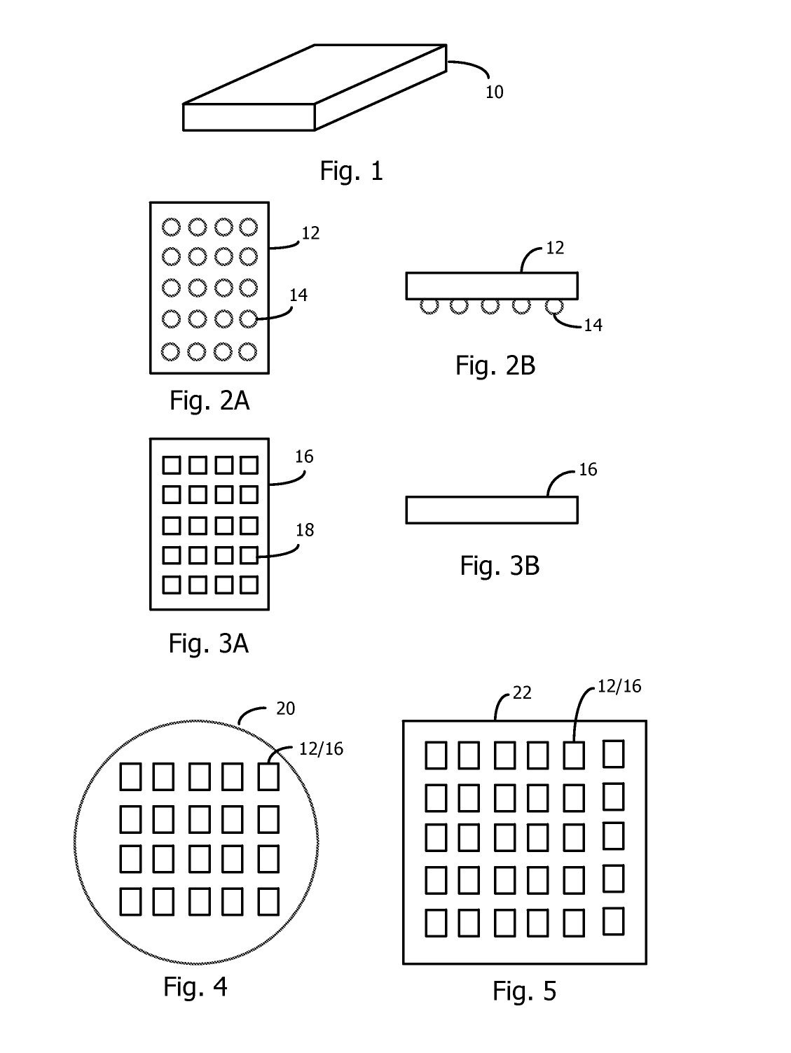

FIG. 1 illustrates the top and side surfaces of a conventional package 10 for a circuit, such as an integrated circuit. The package body will typically be a molded plastic or a ceramic material. The circuitry is to be shielded for EMI purposes by conformally coating the top and side surfaces of the package with a continuous metal layer. The metal will typically be Al, Cu, Ta, Ti, Ni, W, or other suitable metal or alloy.

Two examples of very popular packages will be described.

FIG. 2A is a bottom view of a ball grid array (BGA) package 12, and FIG. 2B is a side view of the BGA package 12. The balls 14 may be any suitable metal including Au, Ni, Sn, Cu, Ag, Pb and alloys thereof. The balls 14 serve as electrodes for the circuit housed in the package body. The balls 14 may melt with heat after the package is positioned over corresponding metal pads on a printed circuit board (PCB) to solder the balls 14 to the pads. Alternatively, the balls 14 are ultrasonically welded to the pads of the PCB. The balls 14 are typically between 50-400 microns in diameter. The number and size of the balls 14 depend on the required number of circuit terminals and available area of the package.

FIG. 3A is a bottom view of a land grid array (LGA) package 16, and FIG. 3B is a side view of the LGA package 16. With an LGA package, the terminals of the package are flat metal lands 18 on the bottom surface. The lands 18 serve as electrodes for the circuit housed in the package body. The package body may be molded to form a solder mask around each land, so the lands do not extend below the package body (as evidenced by the lands 18 not being visible in FIG. 3B). Even if the package body does not form a solder mask, the lands 18 are so thin (e.g., less than 10 microns) that there is no issue with any significant amount of metal material getting under the package and shorting out the lands 18 during the metal deposition step of the process. To electrically connect the lands 18 to pads on a PCB, a solder is provided and melted.

The BGA package presents the most difficulty when efficiently forming a metal shield over the top and sides of the package.

As shown in FIGS. 4 and 5, in one embodiment of the invention, a rigid carrier wafer is provided, whose size will typically be a standard size for processing in a conventional PVD chamber. Typical carrier wafer sizes are 200 mm and 300 mm in diameter. FIG. 4 shows a circular carrier wafer 20, while FIG. 5 shows a square carrier wafer 22. Either shape carrier wafer may be used in the examples. In both cases, the wafers are populated with an array of the packages 12 or 16, or other types of package. Hundreds or thousands of packages 12/16 will typically be mounted on a single carrier wafer, and multiple carrier wafers at a time may be processed in the PVD chamber. This is referred to as batch processing and is very efficient. The carrier wafers 20/22 are reusable. Practical carrier wafer materials include glass, silicon, ceramic, metal or other materials that can withstand the temperatures of the PVD process.

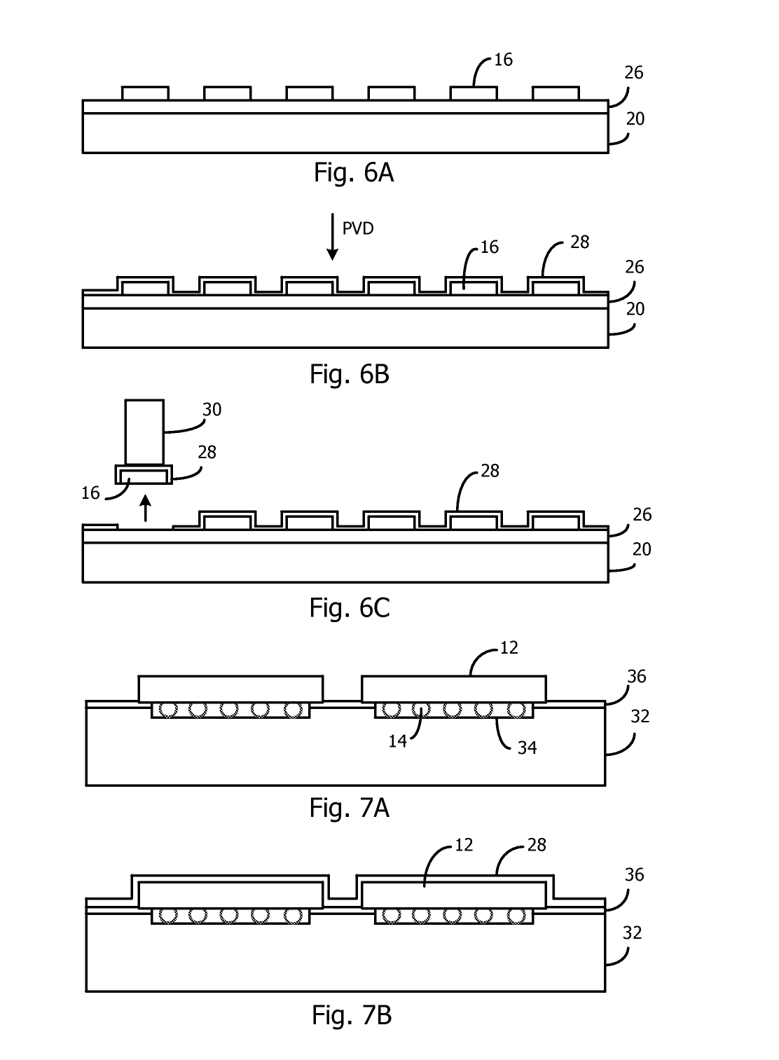

FIGS. 6A-6C are directed to batch processing LGA packages 16 for EMI shielding. It is assumed the circular carrier wafer 20 is used, but the square carrier wafer 22 can be used in all examples. Most of the following figures show a cross-sectional view of a small portion of the carrier wafer.

In FIG. 6A, on the carrier wafer 20 is formed a tacky adhesive layer 26. The adhesive layer 26 adheres more firmly to the carrier wafer 20 then to the bottom surface of the packages 16. This may be because there is much less surface area of the package 16 contacting the adhesive layer 26 than the underlying surface area of the carrier wafer 20, or the adhesive material has a greater adherence to the carrier wafer material than the package body material, or an intermediate layer is provided between the adhesive layer 26 and the carrier wafer 20 that increases the adherence to the carrier wafer 20.

The adhesive layer 26 may be resilient to firmly contact all areas of the bottom surface of the package 16. Suitable adhesives are readily commercially available, such as from 3M Corporation and elsewhere, and are well-known.

The adhesive layer 26 may be deposited by spraying, spin coating, lamination, or other technique.

The packages 16 may be precisely positioned using a programmed pick and place (P&P) machine, or the packages 16 may be transferred in bulk from a tray or tape where the carrier wafer 20 with the adhesive layer 26 is pressed over the arranged packages 16, followed by removal of the tray or tape.

Due to the slight resilience of the adhesive layer 26, there is an adequate seal around at least the periphery of the package 16.

In FIG. 6B, multiple identical carrier wafers populated with the packages 16 are introduced into a PVD chamber, such as a conventional sputtering or evaporation chamber. The target(s) in the sputtering chamber are composed of the metal to be deposited, such as Al, Cu, Ti, etc. A vacuum is pulled and the carrier wafer 20 is heated to about 200° C. for performing a conventional metal deposition process. In sputtering and evaporation, metal particles on an atomic scale are broken loose from the source material and effectively form a metal mist that solidifies over the packages and carrier wafer surface. The deposition process is stopped when the deposited conformal metal film 28 is about 3-5 microns thick. All exposed surfaces will have a conformal layer of the metal deposited over it. The carrier wafers 20 are then removed from the PVD chamber.

In FIG. 6C, a small vacuum nozzle 30 of a conventional programmed pick and place (P&P) machine secures to a center area of each package 16, in turn, and pulls vertically up on the single package 16. The metal film 28 is so thin that it tears along the bottom edges of the package. The metal deposition process does not perform a high temperature anneal so the deposited metal particles are not strongly bonded to each other, but a good electrical shield is nevertheless created. When the packages are vertically pulled up by the nozzle 30, the point at which the metal film on the vertical sides of the package meets the horizontal metal film over the carrier wafer is the weakest link of the metal film, since the metal film adheres relatively strongly to the vertical sides of the package body and the carrier wafer, but the shear strength of the metal film is very low.

After all the packages 16 are removed from the carrier wafer 20, the carrier wafer 20 is stripped of the adhesive layer 26, using a suitable solvent, and cleaned for reuse. If any adhesive material remains on the packages 16, the packages 16 are cleaned with the solvent.

The remaining embodiments deal with the more difficult problem of efficiently shielding a BGA package 12, since the BGA must not be exposed during the metal deposition process or else the metal particles may short two or more balls along an edge of the package 12.

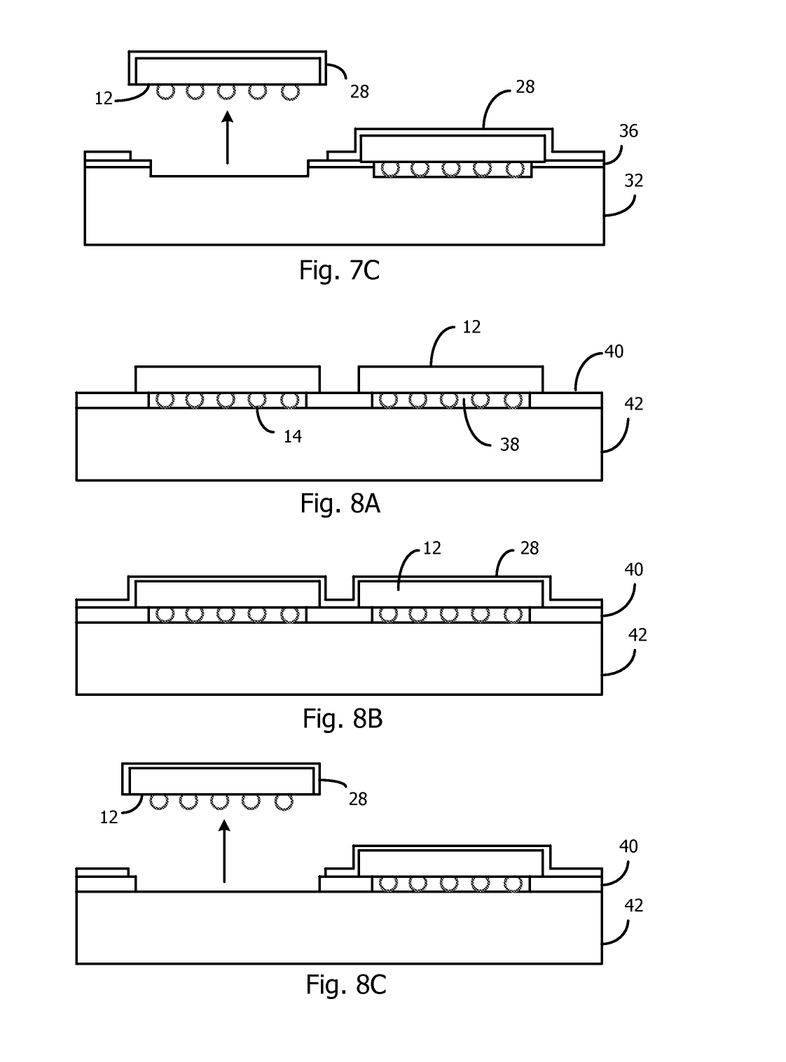

In FIG. 7A, a carrier wafer 32 is provided with etched or molded recesses 34 that are slightly smaller than the footprint of the BGA package 12 and slightly larger than the BGA area.

A tacky adhesive layer 36, which may be the same as the adhesive layer in FIG. 6A, is provided over the carrier wafer 32 between the recesses.

The packages 12 are then positioned, such as individually with a programmed P&P machine or in bulk, so that the BGA is within the recesses 34 but the perimeter of the package bodies are supported by the top surface of the adhesive layer 36 surrounding each recess 34, forming a seal. The depth of the recesses 34 must be sufficient so that the thickness of the BGA does not interfere with the seal around the packages 12.

In FIG. 7B, the populated carrier wafers 32 are then placed in a PVD chamber, and a metal film 28 is deposited to a thickness of about 3-5 microns, as previously described.

In FIG. 7C, each package 12 is removed from the carrier wafer 32 by a vacuum nozzle in the same way described with respect to FIG. 6C, with the metal film 28 tearing along the edges of the package 12.

The carrier wafer 32 is then cleaned for reuse.

FIG. 8A illustrates a process where the BGA packages 12 are positioned in openings 38 in a tacky adhesive layer 40 on a carrier wafer 42. The openings 38 are sized so that the BGA is within the opening 38 but the perimeter of the package bodies are supported by the top surface of the adhesive layer 40. The thickness of the adhesive layer 40 is equal to or greater than the thickness of the BGA so the BGA does not interfere with the seal around the packages 12.

In FIG. 8B, the exposed surfaces of the packages 12 and carrier wafer 42 are conformally coated with a metal film 28, about 3-5 microns thick, in a PVD chamber, as previously described.

In FIG. 8C, the packages 12 are lifted off the carrier wafer 42 by a conventional P&P machine, as previously described, where the metal film 28 tears along the edges of the package 12 due to the thinness and weak bonding of the metal particles.

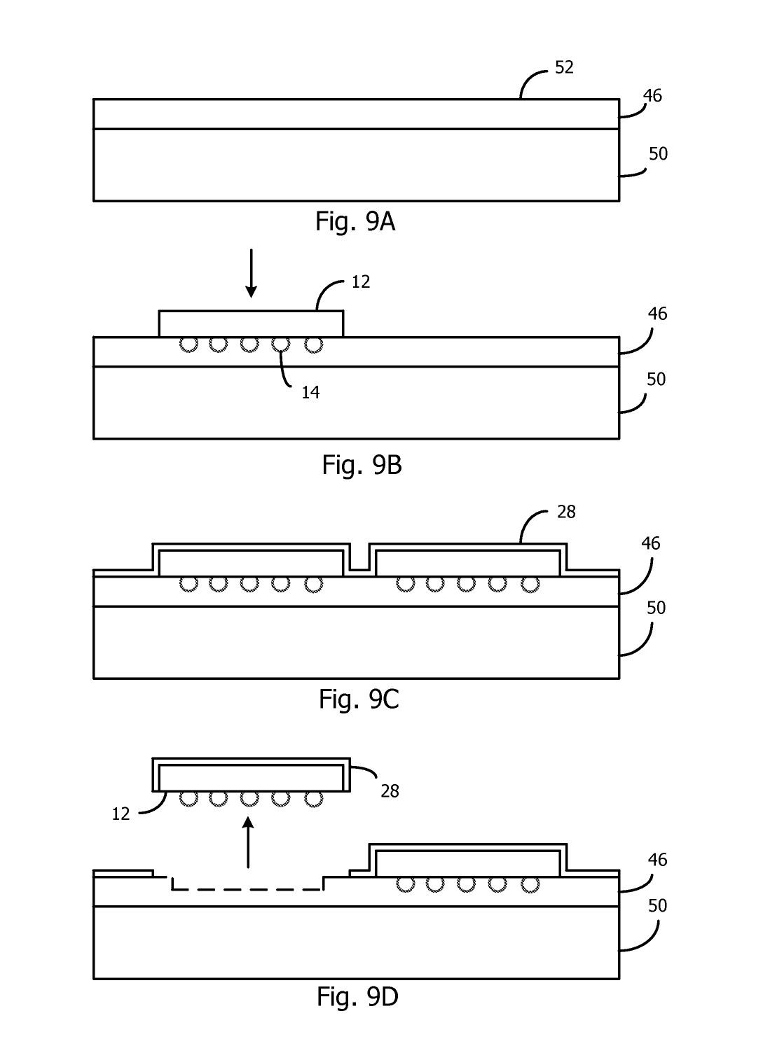

In FIG. 9A, a spongy adhesive layer 46 is deposited on a carrier wafer 50. A gas may be infused in the adhesive material to make the adhesive layer 46 porous. Such techniques are well known. The adhesive material is of a type that cures quickly upon contact with air so as to form a cured thin surface layer 52. The air evaporates solvents in the adhesive material to harden the surface layer 52, but the surface layer 52 remains tacky. The surface layer 52 seals the underlying adhesive material, so the underlying adhesive material remains soft and tacky.

In FIG. 9B, the packages 12 are pushed into the adhesive layer 46 so that the BGA extends through the surface layer 52, and the surface layer 52 forms a seal around the perimeter of the package 12. Forming the harder surface layer 52 is optional if the bulk adhesive material provides sufficient support for the package 12 during the metal deposition process.

In FIG. 9C, the carrier wafers 50 are placed in the PVD chamber, and the metal film 28 is deposited as previously described.

In FIG. 9D, the shielded packages 12 are lifted off the carrier wafer 50 as previously described, and the carrier wafer 50 is cleaned and reused.

FIG. 12, to be described later, shows a process that may be used if the porous adhesive adheres too firmly to the BGA, as a result of partial hardening during the metal deposition process.

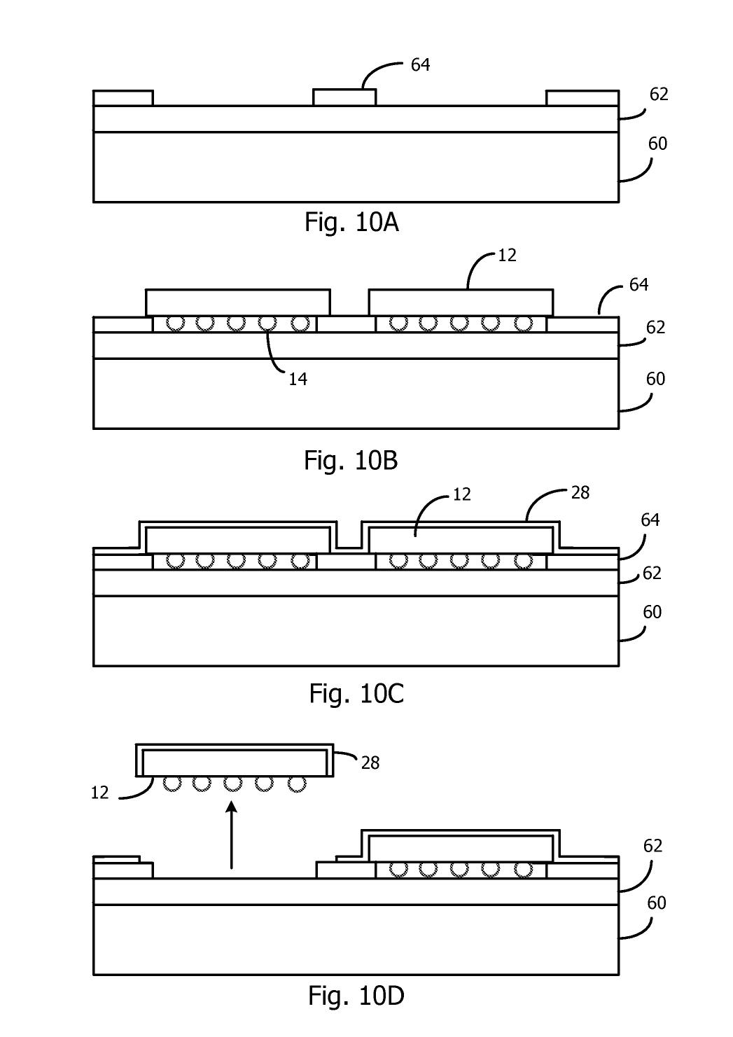

FIG. 10A illustrates a carrier wafer 60 having a resilient tacky adhesive layer 62, with a thin spacer 64 (a stencil) positioned over the adhesive layer 62. The spacer 64 may be formed from a metal sheet by stamping, laser cut, etc. The thickness of the spacer 64 is approximately equal to the thickness of the BGA. The rectangular openings in the spacer 64 are slightly smaller than the package 12 footprint and slightly larger than the BGA area.

FIG. 10B shows the packages 12 positioned so that the BGA contacts the adhesive layer 62 and a seal is formed around the perimeter of the packages 12 with the spacer 64. The spacer 64 is thin and resilient so pressing down on the packages 12 allows the balls 14 to make good contact with the adhesive layer 64 and creates a better seal around the package 12.

In FIG. 10C, the carrier wafers 60 are placed in a PVD chamber, and the conformal metal film 28 between 3-5 microns is deposited over the exposed surfaces, as previously described.

In FIG. 10D, the shielded packages 12 are lifted off the carrier wafer 60 as previously described, and the carrier wafer 60 is cleaned and reused.

In a related embodiment, the top surface of the spacer 64 is provided with a thin adhesive layer to form a better seal between the perimeter of the packages 12 and the spacer 64.

For batch processing of packages, it is conventional to use a stretchable tacky tape supported by a frame to temporarily hold the packages in place for further processing. Such a tape and frame may be use instead of a rigid carrier wafer.

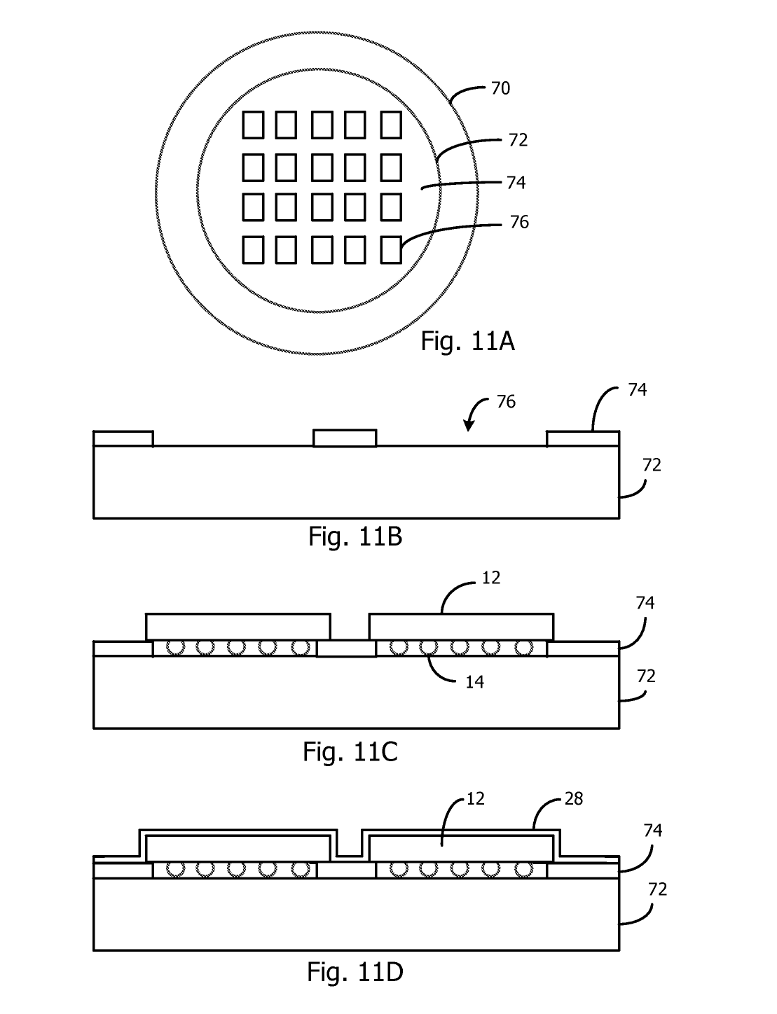

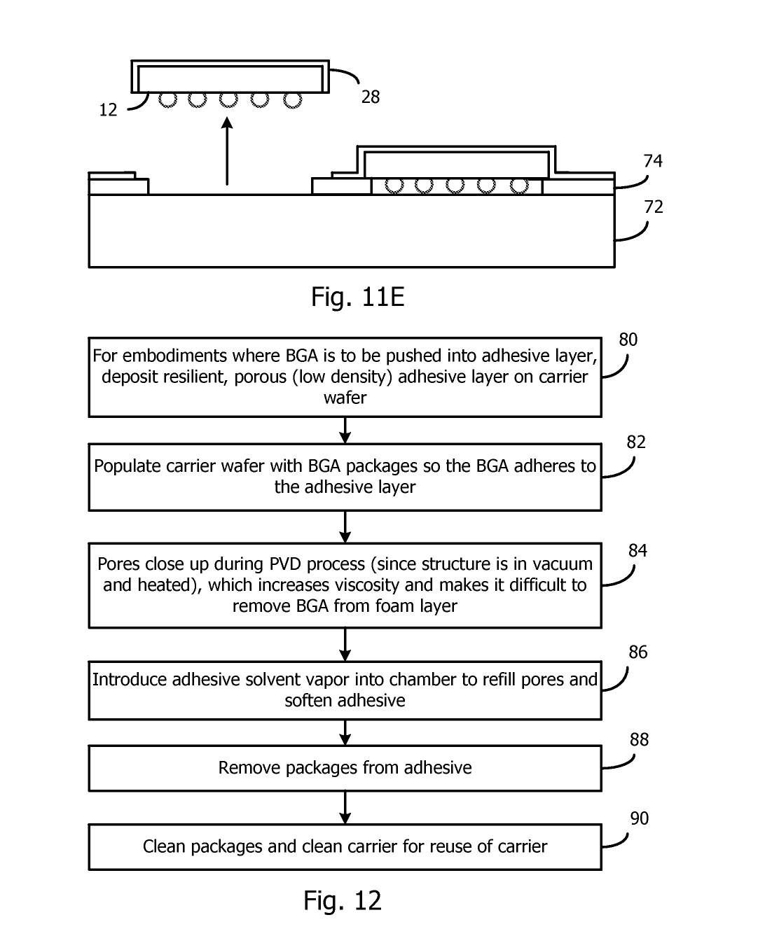

FIG. 11A illustrates a rigid frame 70 supporting a conventional stretchable tacky tape 72 that is commercially sold for use in package processing. A metal spacer 74 (a stencil) is adhered to the tape 72, as better shown in FIG. 11B. The spacer 74 has rectangular openings 76 that are slightly smaller than the package 12 footprint and slightly larger than the BGA area. As in FIG. 10A, the thickness of the spacer 74 is approximately equal to the thickness of the BGA.

In FIG. 11C, the BGA packages 12 are positioned so that the balls 14 contact the tacky tape 72 and the perimeter of the package body forms a seal with the spacer 74. The tape 72 has some resiliency, so pushing down on the packages 12 ensures the balls 14 contact the tacky tape 72 and creates a better seal around the perimeter. In another embodiment, a thin adhesive layer is provided over the top surface of the spacer 74 to adhere to the perimeter of the bottom surface of the package body.

In FIG. 11D, the structures are placed in a PVD chamber, and the conformal metal film 28 between 3-5 microns is deposited over the exposed surfaces, as previously described.

In FIG. 11E, the shielded packages 12 are lifted off the tape 72 and spacer 74 as previously described. The tacky tape 72 is then usually disposed of, but the frame 70 and spacer 74 are cleaned and reused.

In embodiments where the BGA is embedded in a soft porous adhesive layer, such as in FIGS. 9C and 10C, the pores may compress during the processing, such as during the PVD process under heat and in a vacuum environment. This causes the adhesive layer to be denser, which may effectively lock the BGA in the adhesive layer. FIG. 12 identifies steps to enable the BGA to be easily released from the adhesive layer after the metal deposition step.

In step 80 of FIG. 12, a porous adhesive layer is deposited over the carrier wafer to form a low density, resilient adhesive layer. This may be done by infusing a gas into the adhesive material before deposition.

In step 82, the BGA packages are positioned on the carrier wafer, and the BGA adheres to the adhesive layer. The soft adhesive layer may partially wrap around the balls if the package is pressed into the adhesive layer.

In step 84, the pores close up somewhat due to the heat (e.g., 200° C.) and vacuum environment of the PVD process. This increases the viscosity of the adhesive layer, which would increase the required pulling force needed to remove the packages from the carrier wafer.

In step 86, to reduce the adhesion to the balls, a solvent vapor (e.g., alcohol) is introduced into the PVD chamber or into a vacuum chamber other than the PVD chamber after the metal deposition step. This solvent fills the pores via any openings between the packages and the adhesive and dissolves/softens the adhesive. The solvent may be the same solvent that made up the adhesive prior to curing when forming the adhesive layer on the carrier wafer.

In step 88, the packages are easily removed from the adhesive layer with a P&P tool.

In step 90, the packages are cleaned, and the carrier wafer is cleaned for reuse.

Various ones of the described steps may be combined to create other processes suitable for a particular package design.

Having described the invention in detail, those skilled in the art will appreciate that, given the present disclosure, modifications may be made to the invention without departing from the spirit and inventive concepts described herein. Therefore, it is not intended that the scope of the invention be limited to the specific embodiments illustrated and described.

What is claimed is:

1. A method for shielding packaged circuitry comprising:
providing a plurality of ball grid array (BGA) packages, each package comprising a package body housing a circuit, the package body having a top surface and side surfaces, wherein the package has an array of metal balls located on a bottom surface of the package body, wherein the balls have a thickness and extend below the bottom surface of the package body;
providing a rigid, reusable carrier wafer;
providing an adhesive layer on the carrier wafer;
mounting the packages on the carrier wafer such that the balls are not exposed during a subsequent metal film deposition step;
depositing a metal film over the top surface and side surfaces of the package body of each of the packages and over a surface of the carrier wafer between the packages using a physical vapor deposition (PVD) process, while the balls are protected from the metal film; and
removing each of the packages from the carrier wafer by lifting each package while tearing the metal film along bottom edges of the package, resulting in shielded BGA packages.

2. The method of claim 1 wherein the metal film is less than 5 microns thick.

3. The method of claim 1 wherein the carrier wafer has recesses in which the balls of each BGA package are located during the step of depositing the metal film, wherein a perimeter of the bottom surface of the package forms a seal around each of the recesses to protect the balls during the step of depositing the metal film.

4. The method of claim 3 wherein the perimeter of the bottom surface of the package contacts a top surface of the adjective layer around each of the recesses to form the seal around each of the recesses.

5. The method of claim 1 wherein the adhesive layer has openings for the balls in each of the packages, wherein a thickness of the adhesive layer is at least as thick as the balls, wherein a perimeter of the bottom surface of the package body forms a seal with the adhesive layer to protect the balls during the step of depositing the metal film.

6. The method of claim 1 wherein the adhesive layer is resilient and has a thickness at least as thick as the balls, wherein each package is pushed into the adhesive layer so that the balls extend below a top surface of the adhesive layer and a perimeter of the bottom surface of the package body forms a seal around the balls to protect the balls during the step of depositing the metal film.

7. The method of claim 1 further comprising a spacer having an opening for each of the packages, wherein the balls of each package are located within the openings during the step of depositing the metal film, wherein a perimeter of the bottom surface of the package forms a seal around each of the openings to protect the balls during the step of depositing the metal film.

8. The method of claim 7 wherein the seal is between the bottom surface of the package and the spacer.

9. The method of claim 7 wherein the seal is created between a second adhesive layer formed over the spacer and the bottom surface of the package.

10. The method of claim 1 wherein the balls of the package are embedded in the adhesive layer, the method further comprising:
after the step of depositing the metal film, applying a solvent vapor to the adhesive layer to at least partially dissolve the adhesive layer to reduce adhesion to the balls when removing each of the packages from the carrier wafer.

11. The method of claim 1 wherein the step of removing each of the packages comprises removing each of the packages by a vacuum nozzle of a programmed pick and place machine.

12. A method for shielding packaged circuitry comprising:
providing a plurality of ball grid array (BGA) packages, each package comprising a package body housing a circuit, the package body having a top surface and side surfaces, wherein the package has an array of metal balls located on a bottom surface of the package body, wherein the balls have a thickness and extend below the bottom surface of the package body;
providing a stretchable, tacky tape over a frame;
providing a spacer over the tape, the spacer having an opening for each of the packages;
mounting the packages over the spacer such that the balls of each package are located within the openings during a subsequent step of depositing a metal film, wherein a perimeter of the bottom surface of the packages forms a seal around each of the openings to protect the balls during the step of depositing the metal film;
depositing a metal film over the top surface and side surfaces of the package body of each of the packages and over a surface of the spacer between the packages using a physical vapor deposition (PVD) process, while the balls are protected from the metal film; and
removing each of the packages from the tape by lifting each package while tearing the metal film along bottom edges of the package, resulting in shielded BGA packages.

13. The method of claim 12 further comprising forming an adhesive layer over the spacer wherein the seal around each of the openings is between the adhesive layer and the perimeter of the bottom surface of the package.

14. A method for shielding packaged circuitry comprising:
providing a plurality of land grid array (LGA) packages, each LGA package comprising a package body housing a circuit, the package body having a top surface and side surfaces, wherein the package has an array of metal lands located on a bottom surface of the package body;
providing a rigid, reusable carrier wafer;
providing an adhesive layer on the carrier wafer;
mounting the packages on the carrier wafer such that the lands are not exposed during a subsequent metal film deposition step;
depositing a metal film over the top surface and side surfaces of the package body of each of the packages and over a surface of the carrier wafer between the LGA packages using a physical vapor deposition (PVD) process; and
removing each of the packages from the carrier wafer by lifting each LGA package while tearing the metal film along bottom edges of the LGA package, resulting in shielded LGA packages.

15. The method of claim 14 wherein the metal film is less than 5 microns thick.

16. The method of claim 14 wherein the step of removing each of the packages comprises removing each of the packages by a vacuum nozzle of a programmed pick and place machine.
